(19) United States
(12) Patent Application Publication
(10) Pub. No.: US 2013/0201650 A1
(43) Pub. Date: Aug. 8, 2013

(54) MOLDED RADIO-FREQUENCY STRUCTURE WITH SELECTIVE ELECTROMAGNETIC SHIELDING AND FORMING METHOD THEREOF

(71) Applicants: Lee-Cheng SHEN, Hsinchu City (TW); Tsung-Ying HSIEH, Hsinchu City (TW)

(72) Inventors: Lee-Cheng SHEN, Hsinchu City (TW); Tsung-Ying HSIEH, Hsinchu City (TW)

(73) Assignee: Quanta Computer Inc., Tao Yuan Shien (TW)

(21) Appl. No.: 13/449,691

(22) Filed: Apr. 18, 2012

(30) Foreign Application Priority Data
Feb. 4, 2012 (TW) 101103699

(51) Int. Cl. H05K 9/00

(52) U.S. Cl. 361/818

(57) ABSTRACT

A molded radio-frequency (RF) structure with electromagnetic shielding includes a substrate layer, an RF layer, a molded layer and a metal layer. The RF element is disposed on the substrate layer. The molded layer is located on the substrate layer and overlays the RF element. The metal layer is coated on the molded layer, and has an opening located above the RF element.

This application claims the benefit of Taiwan application Serial No. 101103699, filed Feb. 4, 2012, the subject matter of which is incorporated herein by reference.

### BACKGROUND OF THE INVENTION

1. Field of the Invention

The invention relates a molded radio-frequency (RF) structure with electromagnetic shielding and a forming method thereof.

2. Description of the Related Art

As a result of miniaturization of circuit systems, a large number of circuits or circuits of different types are placed very closely to one another. For example, microprocessors, digital signal processors, memories or RF transceiving circuits may all be disposed within a small area of a single printed circuit board. To ensure reliable operations, mutual coupling or interference between the circuits must be isolated. Meanwhile, a metal case is also required for placing certain sensitive circuits therein to quarantine the sensitive circuits from interference generated by internal or external coupling signals.

### SUMMARY OF THE INVENTION

The invention is directed to a molded radio-frequency (RF) structure with electromagnetic shielding and formation method thereof. Through selective electromagnetic shielding, electromagnetic compatibility of the molded structure having electromagnetic shielding is improved.

According to a first aspect of the present invention, a molded RF structure having electromagnetic shielding is provided. The molded RF structure with electromagnetic shielding includes a substrate layer, an RF layer, a molded layer and a metal layer. The RF element is disposed on the substrate layer. The molded layer is located on the substrate layer and overlays the RF element. The metal layer is coated on the molded layer, and has an opening located above the RF element. Electromagnetic shielding effects are provided by connecting the metal layer and the substrate layer to ground.

According to a second aspect of the present invention, a formation method of a molded RF structure with electromagnetic shielding is provided. The method includes steps of: providing a substrate layer and disposing an RF element on the substrate layer; providing a molded layer on the substrate layer and overlaying the molded layer on the RF element; and providing a metal layer coated on the molded layer, the metal layer having an open located above the RF element.

According to a third aspect of the invention, a molded RF structure with electromagnetic shielding is provided. The molded RF structure with electromagnetic shielding includes a substrate layer, an RF element, a molded layer, a metal layer and at least one rib structure. The RF element is disposed on the substrate layer. The molded layer is located on the substrate layer and overlays the RF element. The metal layer is coated on the molded layer. The at least one rib structure is located in the molded layer, and connects the metal layer and the substrate layer to a ground potential to form electric conduction.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1 is a schematic diagram of a molded RF structure according to an embodiment.

FIG. 2 is a flowchart of a partial process of a formation method of a molded RF structure with electromagnetic shielding according to a first embodiment of the present invention.

FIG. 3 is a flowchart of a partial process of a formation method of a molded RF structure with electromagnetic shielding according to a second embodiment of the present invention.

FIG. 4 is a flowchart of a partial process of a formation method of a molded RF structure with electromagnetic shielding according to a third embodiment of the present invention.

FIG. 5 is a schematic diagram of a molded RF structure according to another embodiment.

FIG. 6 is a schematic diagram of a molded RF structure according to yet another embodiment.

### DETAILED DESCRIPTION OF THE INVENTION

In a molded RF structure with electromagnetic shielding and formation method thereof disclosed by the present invention, selective electromagnetic shielding is provided to improve electromagnetic compatibility of the molded structure having electromagnetic.

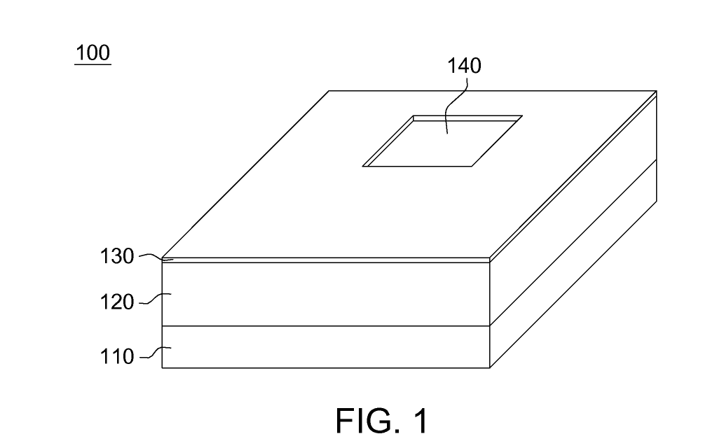

FIG. 1 shows a schematic diagram of a molded RF structure according to an embodiment. A molded RF structure with electromagnetic shielding 100 includes substrate layer 110, an RF element (not shown), a molded layer 120 and a metal layer 130. For example, the RF element is an RF transceiving circuit disposed on the substrate layer 110. The molded layer 120 is located on the substrate layer 110 and overlays the RF element. The metal layer 130 is coated on the molded layer 120, and has an opening. The opening is located above the RF element. The metal layer 130 and the substrate layer 110 are connected to ground to provide electromagnetic shielding effects.

By implementing the coating metal layer 130 for replacing a conventional metal case, the above molded RF structure 100 with electromagnetic shielding is offered with a reduced thickness. However, it likely that mutual coupling between the metal layer 130 and the RF element degrades the overall performance. Therefore, an opening 140 is selectively provided at the metal layer 130 above the RF element to reduce the desirable effects of the metal layer 130 on the RF element. That is, in the molded RF structure 100 with electromagnetic shielding, the metal layer 130 is selectively coated on the molded layer 120 located above the RF element.

According to the present invention, a formation method for a molded RF structure with electromagnetic shielding include steps of: providing a substrate layer and disposing an RF element on the substrate layer; providing a molded layer on the substrate layer and overlaying the molded layer on the RF element; and providing a metal layer coated on the molded layer, the metal layer having an open located above the RF element.

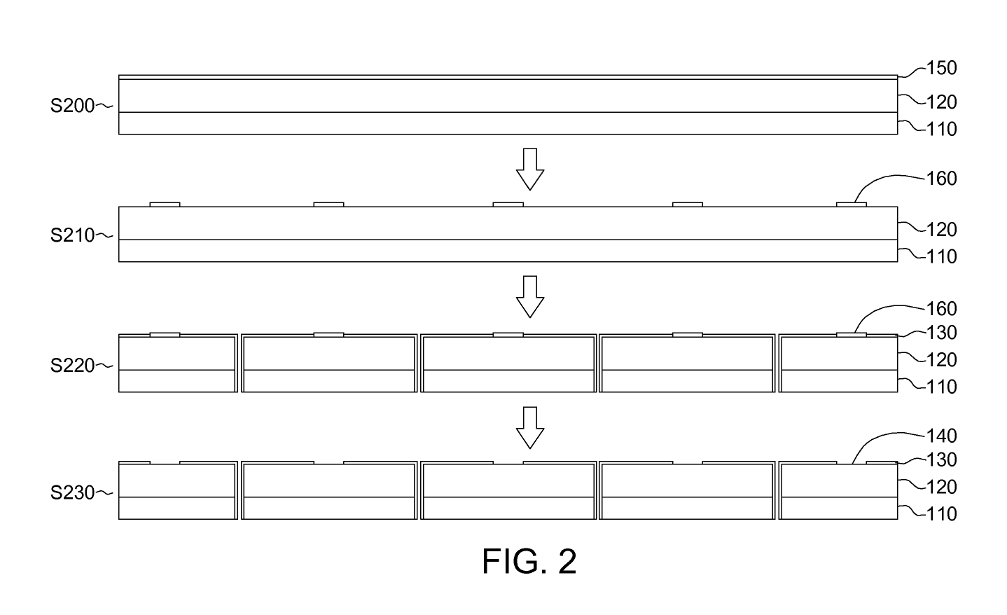

FIG. 2 shows a flowchart of a partial process of a formation method of a molded RF structure with electromagnetic shielding according to a first embodiment of the present invention. In Step S200, a photoresist layer 150 is provided on the molded layer 120. In Step S210, the photoresist layer 150 is exposed and defined to obtain an area 160 corresponding to the opening 140. The photoresist layer in the area 160 is not removed. In Step S220, singulation is performed to overlay the metal layer 130 on the molder layer 120. In Step S230, photoresist stripping is performed to ablate the photoresist layer in the area 160 to obtain the opening 140.

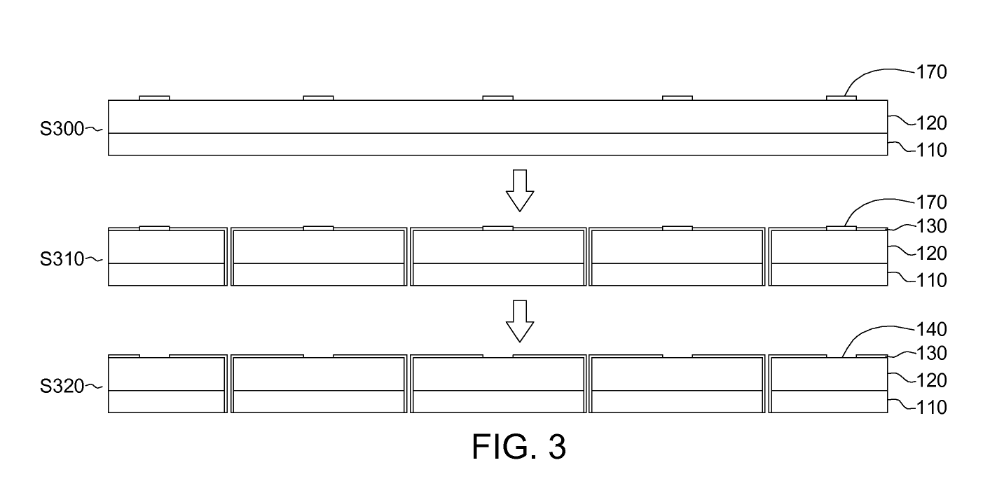

FIG. 3 shows a flowchart of a partial process of a formation method of a molded RF structure with electromagnetic shielding according to a second embodiment of the present invention. In Step S300, stencil printing is performed on the molded layer 120 to form a sacrifice layer 170 for corresponding to the opening 140. In Step S310, singulation is performed to overlay the metal layer 130 on the molder layer 120. In Step 320, the sacrifice layer 170 is ablated to obtain the opening 140.

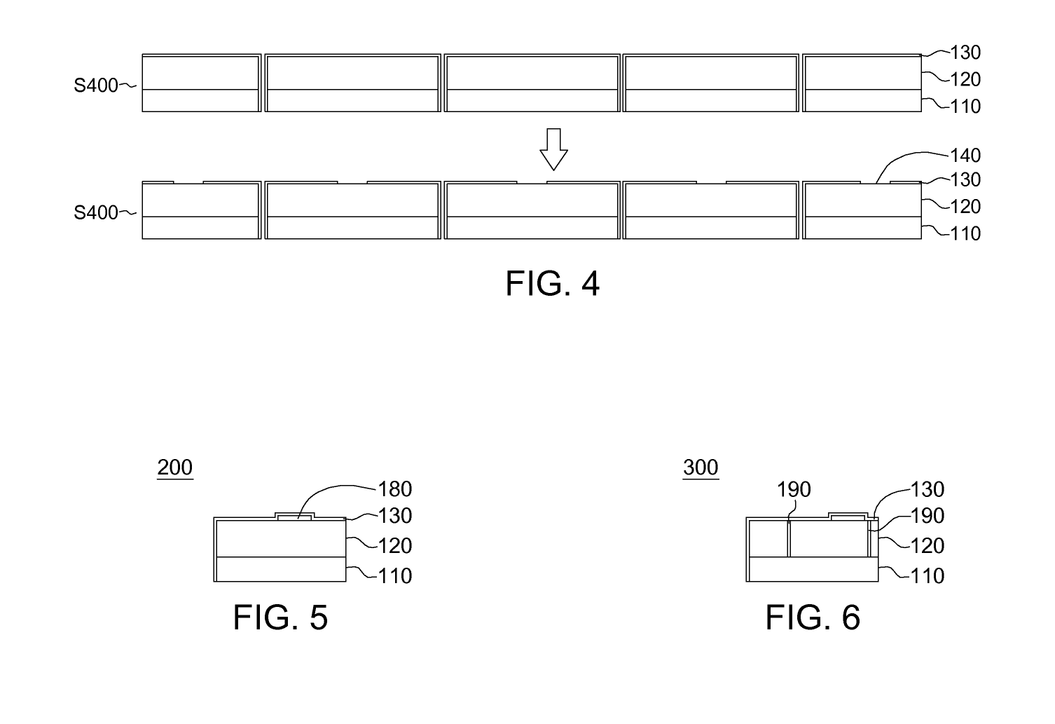

FIG. 4 shows a flowchart of a partial process of a formation method of a molded RF structure with electromagnetic shielding according to a third embodiment of the present invention. In Step S400, singulation is performed to overlay the metal layer 130 on the molder layer 120. In Step S410, a metal layer in an area corresponding to the opening 140 is ablated through laser to obtain the opening 140.

A molded RF structure with electromagnetic shielding is further disclosed according to another embodiment of the present invention. FIG. 5 shows a schematic diagram of a molded RF structure with electromagnetic shielding according to another embodiment of the present invention. A molded RF structure 200 with electromagnetic shielding includes a substrate layer 110, an RF element (not shown), a molded layer 120, a filler material 180 and a metal layer 130. The RF element is disposed on the substrate layer 110. The molded layer is located on the substrate layer 110 and overlays the RF element. The filler material 180 is coated on the molder layer, and is correspondingly located in an area above the RF element. The metal layer 130 is coated on the molded layer and overlays the filler material 180.

By implementing the coating metal layer 130 for replacing a conventional metal case, the above molded RF structure 200 with electromagnetic shielding is offered with a reduced thickness. The molded RF structure 200 with electromagnetic shielding further utilizes the filler material 180 to increase a distance between the RF element and the metal layer 130 to reduce the undesirable effects of the metal layer 130 on the RF element.

Further, one or several rib structure may be added to the molded RF structure with electromagnetic shielding. The rib structure is located in the molded layer 120 and connects the metal layer and the substrate layer 110 to a potential, e.g., a ground potential, so as to effectively improved undesirable effects generated by harmonic waves. FIG. 6 shows a schematic diagram of a molded RF structure with electromagnetic shielding according to yet another embodiment of the present invention. A molded RF structure 300 with electromagnetic shielding 300 includes a substrate layer 110, an RF element (not shown), a molded layer 120, a metal layer 130 and at least a rib structure 190. The RF element is disposed on the substrate layer 110. The molded layer 120 is located on the substrate layer 110 and overlays the RF element. The metal layer 130 is coated on the molded layer 120. For example, a part of the metal layer 130 corresponding to the RF element may be provided with an opening or be elevated by a filler material. The at least one rib structure 190 is located in the molder layer 120 to connect the metal layer 130 and the substrate layer 110 to a ground potential, so as to form electric conduction to provide electromagnetic shielding effects. For example, the rib structure is a hollow or solid metal post.

Therefore, it is illustrated that in the molded RF structure with electromagnetic shielding and formation method thereof, the metal layer is selectively coated to elude from the RF element, or the metal layer above the RF element is elevated. As a result, not only the thickness of the overall structure is significantly reduced, but also mutual effects between the metal layer and the RF element are reduced through selectively providing electromagnetic shielding to improve electromagnetic compatibility of the molded RF structure with electromagnetic shielding.

While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A molded radio-frequency (RF) structure with electromagnetic shielding, comprising:
a substrate layer;
an RF element, disposed on the substrate layer;
a molded layer, located on the substrate layer and overlaying the RF element; and
a metal layer, coated on the molded layer, having an opening located above the RF element.

2. A formation method of a molded RF structure with electromagnetic shielding, comprising:
providing a substrate layer, and disposing an RF element on the substrate layer;
providing a molded layer on the substrate layer, and overlaying the molded layer on the RF element; and
providing and coating a metal layer on the molded layer, the metal layer having an opening located above the RF element.

3. The formation method according to claim 2, further comprising:
providing a photoresist layer on the molded layer;
exposing the photoresist layer to define an area corresponding to the opening;
singulating and overlaying the metal layer on the molder layer; and
performing photoresist stripping to ablate the photoresist in the area to obtain the opening.

4. The formation method according to claim 2, further comprising:
stencil printing a sacrifice layer on the molded layer to correspond to the opening;
singulating and overlaying the metal layer on the molder layer; and
ablating the sacrifice layer to obtain the opening.

5. The formation method according to claim 2, further comprising:
singulating and overlaying the metal layer on the molder layer; and
ablating an area of the metal layer corresponding to the opening through laser to obtain the opening.

6. A molded RF structure with electromagnetic shielding, comprising:
a substrate layer;
an RF element, disposed on the substrate layer;
a molded layer, located on the substrate layer and overlaying the RF element;
a metal layer, coated on the molded layer; and
at least a rib structure, located in the molded layer, and connecting the metal layer and the substrate layer to a ground potential to form electric conduction.

7. The structure according to claim 6, wherein the rib structure is a hollow metal post.

8. The structure according to claim 6, wherein the rib structure is a solid metal post.
